(19) United States
(12) Patent Application Publication
(10) Pub. No.: US 2020/0061807 A1
(43) Pub. Date: Feb. 27, 2020

(54) INDUSTRIAL ROBOT

(71) Applicant: NIDEC SANKYO CORPORATION, Nagano (JP)

(72) Inventors: Takahiro SHIRAKI, Nagano (JP); Takao NAKAE, Nagano (JP); Shigeyuki KAINO, Nagano (JP)

(21) Appl. No.: 16/466,166

(22) PCT Filed: Nov. 6, 2017
(86) PCT No.: PCT/JP2017/039850

§ 371 Date: Jun. 3, 2019

(30) Foreign Application Priority Data
Dec. 2, 2016 (JP) 2016-234797

(51) Int. Cl. B25J 9/02; B25J 9/06; B65G 49/07; H01L 21/677; B25J 11/00

(52) U.S. Cl. CPC B25J 9/02; B25J 9/06; B25J 11/0095; H01L 21/677; B65G 49/07

(57) ABSTRACT

An industrial robot for use with an object may include a hand on which the object is mounted; an arm having a distal end to which the hand is rotatably connected; a body part to which a base end of the arm is rotatably connected; and an installation member structured to install the body part on a floor surface. The body part may include an elevating body having an upper surface to which the base end of the arm is rotatably connected, a casing configured to hold the elevating body such that the elevating body is movable up and down and to accommodate at least a part of a lower end of the elevating body, and an elevating mechanism configured to move the elevating body up and down. The elevating mechanism may be accommodated in the casing so as to overlap the elevating body when viewed in an up-down direction.

### CROSS-REFERENCE TO RELATED APPLICATIONS

This is the U.S. national stage of application No. PCT/JP2017/039850, filed on Nov. 6, 2017. Priority under 35 U.S.C. § 119(a) and 35 U.S.C. § 365(b) is claimed from Japanese Application No. 2016-234797, filed Dec. 2, 2016; the disclosures of which are incorporated herein by reference.

### TECHNICAL FIELD

At least an embodiment of the present invention relates to an industrial robot configured to transport objects to be transported such as semiconductor wafers.

### BACKGROUND

A conventional horizontal articulated robot configured to transport semiconductor wafers between a FOUP (Front Open Unified Pod) and a semiconductor wafer processing apparatus has been known (see, for example, Patent Literature 1). The horizontal articulated robot described in Patent Literature 1 constituting a part of an EFEM (Equipment Front End Module) is disposed in a casing of the EFEM. The EFEM is disposed on the front side of the semiconductor wafer processing apparatus, and the FOUP is disposed on the front side of the EFEM. The casing of the EFEM is formed in a box shape of an elongated rectangular parallelepiped having a short side in a front-back direction and a long side in a right-left direction.

Further, the horizontal articulated robot described in Patent Literature 1 includes two hands on which semiconductor wafers are mounted, an arm having a distal end to which the two hands are rotatably connected, and a body part to which a base end of the arm is rotatably connected. The body part includes a columnar member having an upper end to which the base end of the arm is rotatably connected, a casing that holds the columnar member such that the columnar member is movable up and down, and an elevating mechanism that moves the columnar member up and down. The columnar member is accommodated in the casing when being moved down. In addition, the elevating mechanism is accommodated in the casing.

### PATENT LITERATURE

[Patent Literature 1] JP2015-36186 A

As described above, the horizontal articulated robot described in Patent Literature 1 is disposed in the casing of the EFEM. Various pipes and wires may be arranged in the casing of the EFEM. In order to secure a space for arranging the pipes and wires in the casing of the EFEM, the thickness of the body part of the horizontal articulated robot is reduced in the front-back direction.

### SUMMARY

Thus, at least an embodiment of the present invention provides an industrial robot in which the thickness of a body part to which a base end of an arm is rotatably connected can be reduced.

In order to solve the aforementioned problem, an industrial robot according to at least an embodiment of the present invention includes a hand on which an object to be transported is mounted, an arm having a distal end to which the hand is rotatably connected, a body part to which a base end of the arm is rotatably connected, and an installation member for installing the body part on a floor surface. The body part includes an elevating body having an upper surface to which the base end of the arm is rotatably connected, a casing configured to hold the elevating body such that the elevating body is movable up and down and to accommodate at least a part of a lower end of the elevating body, and an elevating mechanism configured to move the elevating body up and down. The elevating mechanism is accommodated in the casing so as to overlap the elevating body when viewed in an up-down direction.

In at least an embodiment of the present invention, for example, the casing is formed in a substantially rectangular shape that has a long side in a right-left direction and a short side in a front-back direction when viewed in the up-down direction. The elevating body includes a frame portion formed in a substantially rectangular shape that has a long side in the right-left direction and a short side in the front-back direction when viewed in the up-down direction, the frame portion being accommodated in the casing when the elevating body is moved down.

In the industrial robot according to at least an embodiment of the present invention, the body part includes the elevating body having the upper surface to which the base end of the arm is rotatably connected, the casing configured to accommodate at least a part of the lower end of the elevating body, and the elevating mechanism configured to move the elevating body up and down. The elevating mechanism is accommodated in the casing so as to overlap the elevating body when viewed in the up-down direction. Therefore, in at least an embodiment of the present invention, for example, the casing is formed in the substantially rectangular shape that has the long side in the right-left direction and the short side in the front-back direction when viewed in the up-down direction, and therefore, the width of the casing in the front-back direction can be reduced compared with a case where the elevating mechanism is accommodated in the casing while being displaced from the elevating body in the front-back direction. That is, in at least an embodiment of the present invention, for example, the width of the body part in the front-back direction can be reduced compared with a case where the elevating mechanism is accommodated in the casing while being displaced from the elevating body in the front-back direction. As a result, the thickness of the body part can be reduced.

Here, in a case where the thickness of the body part is reduced, the body part may be unstably installed on the floor surface at the time of installing the industrial robot on the floor surface. Therefore, the industrial robot may be unstably installed on the floor surface. However, the industrial robot according to at least an embodiment of the present invention includes the installation member for installing the body part on the floor surface. Therefore, in at least an embodiment of the present invention, even if the thickness of the body part is reduced, the body part can be stably installed on the floor surface. As a result, the industrial robot can be stably installed on the floor surface.

In at least an embodiment of the present invention, for example, the casing is fixed to the installation member. Further, in at least an embodiment of the present invention, for example, the casing is formed in a substantially rectangular shape that has a long side in a right-left direction and a short side in a front-back direction when viewed in the up-down direction. The installation member includes a casing fixing portion to which the casing is fixed, and two fixed portions to be fixed to the floor surface. The casing fixing portion is disposed on one side of the casing in the front-back direction. The fixed portions are connected to a lower end of the casing fixing portion. One of the two fixed portions is disposed on one side of the casing in the right-left direction, and the other of the two fixed portions is disposed on the other side of the casing in the right-left direction.

In at least an embodiment of the present invention, for example, the body part includes a wiring box fixed to one side surface of the casing in the right-left direction. The wiring box is fixed to an upper end of the casing. In this case, the wiring box can be prevented from interfering with the fixed portions disposed on the outer sides of the casing in the right-left direction.

In at least an embodiment of the present invention, the industrial robot may include an elevating unit configured to move the body part up and down. A second casing that is a casing of the elevating unit may be fixed to the installation member. In this case, even if the thickness of the elevating unit is reduced in addition to the body part, the body part and the elevating unit can be stably installed on the floor surface. As a result, the industrial robot can be stably installed on the floor surface.

As described above, in the industrial robot according to at least an embodiment of the present invention, the thickness of the body part to which the base end of the arm is rotatably connected can be reduced.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1A and FIG. 1B are a perspective view of an industrial robot according to an embodiment of the present invention, FIG. 1A is a front view of the industrial robot and FIG. 1B is a back view of the industrial robot.

FIG. 2 is a perspective view of a state where an elevating body of the industrial robot illustrated in FIG. 1A and FIG. 1B is moved up.

FIG. 3 is a schematic plan view of a semiconductor manufacturing system in which the industrial robot illustrated in FIG. 1 A and FIG. 1B is used.

FIG. 4 is a side view of the industrial robot illustrated in FIG. 1A and FIG. 1B.

FIG. 5 is a cross-sectional view for illustrating the configuration of a cross-section taken along the line E-E in FIG. 4.

FIG. 6 is a perspective view of an installation member illustrated in FIG. 1A and FIG. 1B.

FIG. 7A is a perspective view of the industrial robot according to another embodiment of the present invention, and FIG. 7B is a perspective view of a state where the elevating body and the casing of the industrial robot illustrated in FIG. 7A is moved up.

### DETAILED DESCRIPTION

Hereinafter, at least an embodiment of the present invention will be described with reference to the drawings.

(Whole Configuration of Industrial Robot)

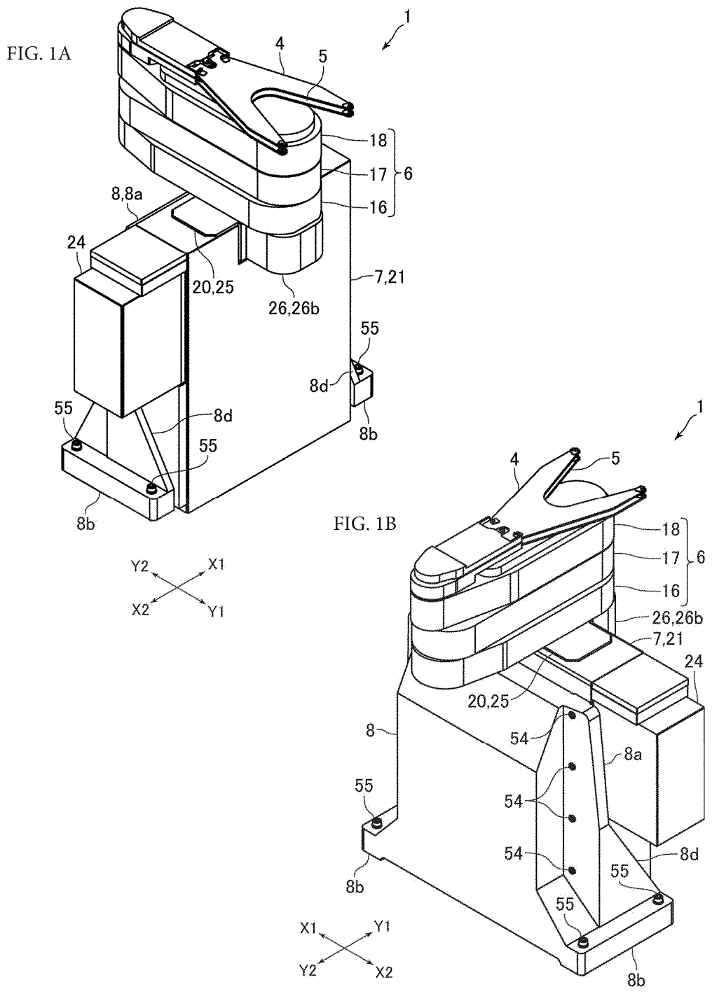

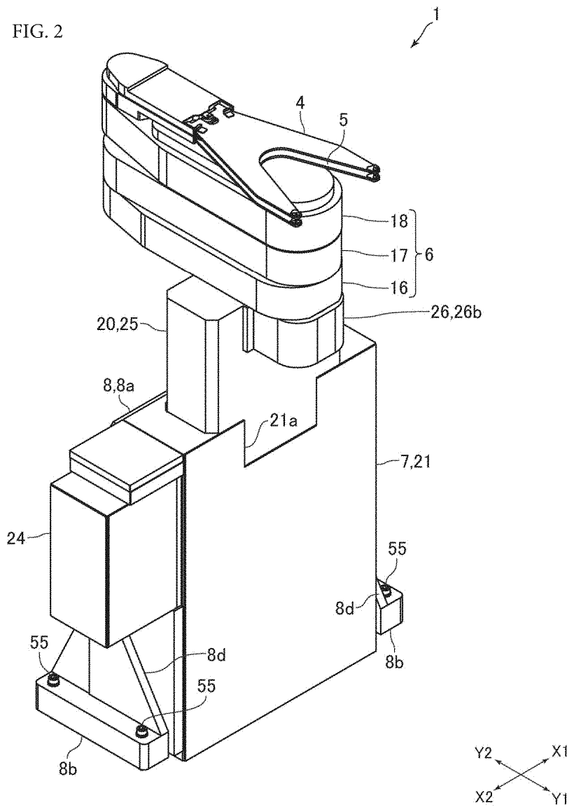

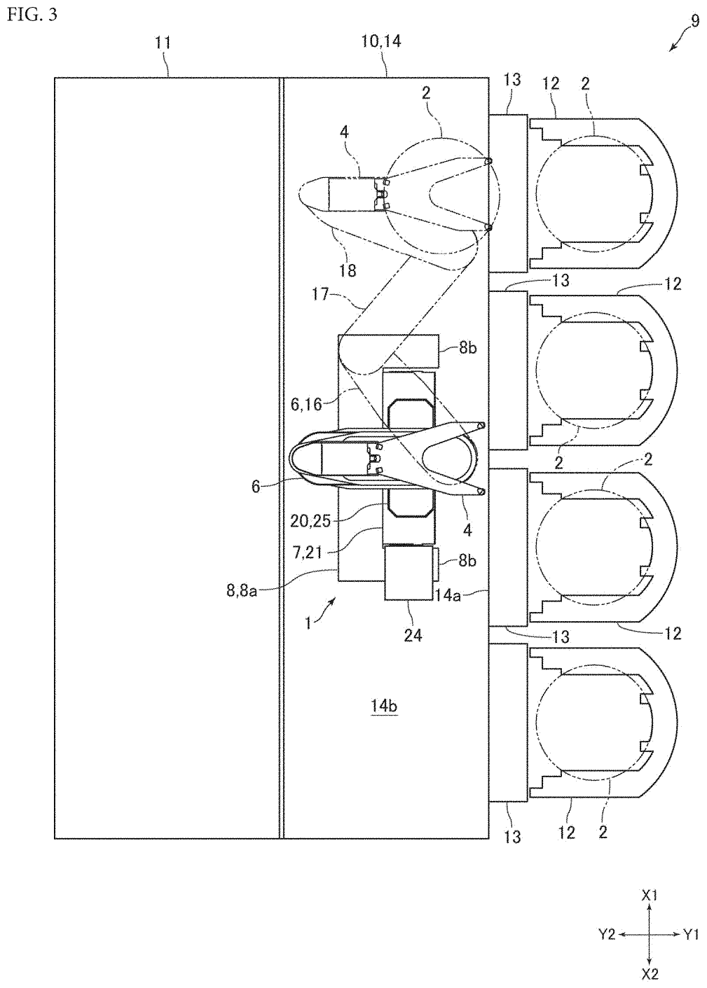

FIG. 1 A and FIG. 1B are a perspective view of an industrial robot 1 according to an embodiment of the present invention. FIG. 1A is a front view of the industrial robot 1 and FIG. 1B is a back view of the industrial robot 1. FIG. 2 is a perspective view of a state where an elevating body 20 of the industrial robot 1 illustrated in FIG. 1 is moved up. FIG. 3 is a schematic plan view of a semiconductor manufacturing system 9 in which the industrial robot 1 illustrated in FIG. 1A and FIG. 1B is used.

The industrial robot 1 of the present embodiment (hereinafter referred to as “robot 1”) is a horizontal articulated robot configured to transport semiconductor wafers 2 (refer to FIG. 3, hereinafter referred to as “wafers 2”) that are objects to be transported. The robot 1 includes two hands 4 and 5 on which each of the wafers 2 is mounted, an arm 6 that has a distal end to which the hands 4 and 5 are rotatably connected, and that operates in a horizontal direction, and a body part 7 to which a base end of the arm 6 is rotatably connected. The robot 1 further includes an installation member 8 for installing the body part 7 on a floor surface (specifically, a floor surface 14b of a casing 14 described below).

In the following description, one direction in the horizontal direction is taken as a right-left direction, and a direction orthogonal to an up-down direction (vertical direction) and a right-left direction is taken as a front-back direction. Also, X1 side of FIG. 1 A and FIG. 1B or the like, which is one side in the right-left direction, is defined as the “right” side, and X2 side of FIG. 1 A and FIG. 1B or the like, which is the other side in the right-left direction, is defined as the “left” side. Y1 side of FIG. 1 A and FIG. 1B or the like, which is one side in the front-back direction, is defined as the “front” side, and Y2 side of FIG. 1 A and FIG. 1B or the like, which is the other side in the front-back direction, is defined as the “back” side.

As illustrated in FIG. 3, the robot 1 is mounted in the semiconductor manufacturing system 9 to be used therein. The semiconductor manufacturing system 9 includes an EFEM 10 and a semiconductor wafer processing apparatus 11 that is configured to perform a predetermined processing on the wafers 2. The EFEM 10 is disposed on the front side of the semiconductor wafer processing apparatus 11. The robot 1 constitutes a part of the EFEM 10. The EFEM 10 further includes a plurality of load ports 13 configured to open and close respective FOUPs 12, and the casing 14 in which the robot 1 is accommodated.

The casing 14 is formed in a box shape of a rectangular parallelepiped elongated in the right-left direction. The load ports 13 are disposed, for example, on the front side of the casing 14. The robot 1 is disposed in the casing 14 such that the base end of the arm 6 is located adjacent to a front surface 14a of the casing 14. Further, the robot 1 is configured to transport the wafers 2 between the FOUPs 12 and the semiconductor wafer processing apparatus 11. In addition, the robot 1 may be disposed in the casing 14 such that the base end of the arm 6 is located adjacent to a back side surface inside the casing 14.

The arm 6 includes a first arm portion 16 having a base end rotatably connected to the body part 7, a second arm portion 17 having a base end rotatably connected to a distal end of the first arm portion 16, and a third arm portion 18 having a base end rotatably connected to a distal end of the second arm portion 17. Each of the first arm portion 16, the second arm portion 17, and the third arm portion 18 is formed in a hollow shape. The body part 7, the first arm portion 16, the second arm portion 17, and the third arm portion 18 are disposed in the up-down direction in this order from the lower side.

Each of the hands 4 and 5 is formed in a substantially Y-shape when viewed in the up-down direction. Base ends of the respective hands 4 and 5 are rotatably connected to a distal end of the third arm portion 18. The hands 4 and 5 are disposed to overlap each other in the up-down direction. Specifically, the hand 4 is disposed on the upper side, and the hand 5 is disposed on the lower side. Also, the hands 4 and 5 are disposed above the third arm portion 18. In addition, the illustration of the hand 5 is omitted in FIG. 3.

(Configuration of Body Part)

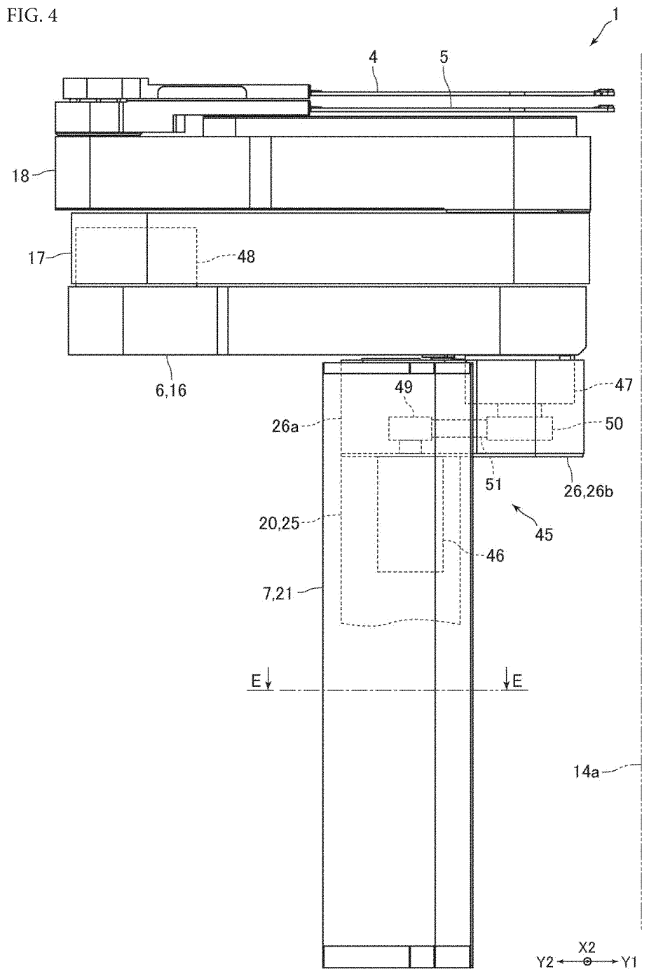

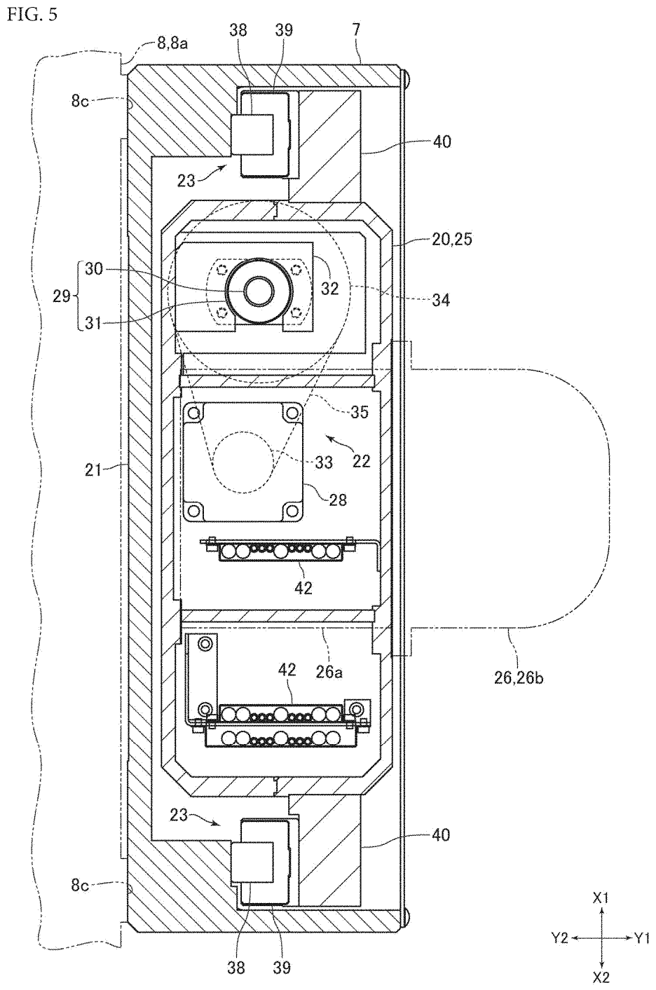

FIG. 4 is a side view of the robot 1 illustrated in FIG. 1 A and FIG. 1B. FIG. 5 is a cross-sectional view for illustrating the configuration of a cross-section taken along the line E-E in FIG. 4. In addition, the illustration of the installation member 8 is omitted in FIG. 4.

The body part 7 includes an elevating body 20 having an upper surface to which the base end of the arm 6 is rotatably connected, a casing 21 configured to hold the elevating body 20 such that the elevating body 20 is movable up and down, an elevating mechanism 22 (see FIG. 5) configured to move the elevating body 20 up and down relative to the casing 21, and guide mechanisms 23 configured to guide the elevating body 20 in the up-down direction. Further, the body part 7 includes a wiring box (cable box) 24 in which wires are accommodated. In addition, the illustration of the wiring box 24 is omitted in FIGS. 4 and 5.

The casing 21 is formed in a box shape of a flat, substantially rectangular parallelepiped, and the shape of the casing 21 when viewed in the up-down direction is a substantially rectangular shape having a long side in the right-left direction and a short side in the front-back direction. Specifically, the shape of the casing 21 when viewed in the up-down direction is a substantially rectangular shape elongated in the right-left direction. The casing 21 has front and back surfaces that are planes orthogonal to the front-back direction, and right and left side surfaces that are planes orthogonal to the right-left direction. Further, the casing 21 has upper and bottom surfaces that are planes orthogonal to the up-down direction.

The wiring box 24 is formed in a box shape of a rectangular parallelepiped. The wiring box 24 is fixed to the left side surface of the casing 21. Also, the wiring box 24 is fixed to an upper end of the casing 21. Various connectors (not illustrated) are disposed on the left side surface of the wiring box 24.

The elevating body 20 includes a frame portion 25 formed as a flat, substantially rectangular parallelepiped, and an upper end frame portion 26 fixed to an upper end of the frame portion 25. The frame portion 25 and the upper end frame portion 26 are separately formed and fixed to each other. Specifically, the frame portion 25 and the upper end frame portion 26 are fixed to each other by a screw (not illustrated).

The frame portion 25 is formed in a box shape having an opening at the bottom side, and the shape of the frame portion 25 when viewed in the up-down direction is a substantially rectangular shape having a long side in the right-left direction and a short side in the front-back direction. Specifically, the shape of the frame portion 25 when viewed in the up-down direction is a substantially rectangular shape elongated in the right-left direction. The frame portion 25 has front and back surfaces that are planes orthogonal to the front-back direction, and right and left side surfaces that are planes orthogonal to the right-left direction. Further, the frame portion 25 has an upper surface that is a plane orthogonal to the up-down direction. The width of the frame portion 25 in the front-back direction is smaller than the width of the casing 21 in the front-back direction, and the width of the frame portion 25 in the right-left direction is smaller than the width of the casing 21 in the right-left direction.

The upper end frame portion 26 is formed in a substantially rectangular parallelepiped shape. The upper end frame portion 26 is formed to have a substantially rectangular shape having a long side in the front-back direction and a short side in the right-left direction when viewed in the up-down direction. Further, the upper end frame portion 26 is formed in a hollow shape. The width of the upper end frame portion 26 in the right-left direction is smaller than the width of the frame portion 25 in the right-left direction.

The upper end frame portion 26 includes a fixed portion 26a fixed to the frame portion 25. The fixed portion 26a is accommodated in a recess that is formed at the upper end of the frame portion 25 to be located in the center in the right-left direction. The upper end frame portion 26 includes a protruding portion 26b connected to a front end of the fixed portion 26a and protruding forward from the front surface of the frame portion 25. The base end of the arm 6 is disposed on an upper surface of the protruding portion 26b and is rotatably connected to the protruding portion 26b.

The frame portion 25 is accommodated in the casing 21 when the elevating body 20 is moved down. Specifically, when the elevating body 20 is moved down to a lower limit position (in a state illustrated in FIG. 1 A and FIG. 1B), the entire frame portion 25 is accommodated in the casing 21. That is, when the elevating body 20 is moved down to the lower limit position, a portion of the elevating body 20 other than the protruding portion 26b is accommodated in the casing 21.

Further, when the elevating body 20 is moved up from the lower limit position (in a state illustrated in FIG. 2), a lower end portion of the frame portion 25 is accommodated in the casing 21. That is, when the elevating body 20 is moved up from the lower limit position, a lower end portion of the elevating body 20 is accommodated in the casing 21. A cut portion 21a (see FIG. 2), in which the protruding portion 26b is disposed when the elevating body 20 is moved down, is formed in the upper end of the front surface of the casing 21. In addition, a cut portion allowing the frame portion 25 to pass therethrough when the elevating body 20 moves up and down is formed in the upper surface of the casing 21.

The elevating mechanism 22 is accommodated in the casing 21. As illustrated in FIG. 5, the elevating mechanism 22 includes a motor 28 and a ball screw 29. The ball screw 29 includes a screw shaft 30 configured to rotate by power of the motor 28, and a nut 31 engaged with the screw shaft 30. The motor 28 is accommodated in the casing 21 and is fixed to a lower end of the casing 21. In addition, the motor 28 is disposed substantially in the central position of the casing 21 in the right-left direction. The screw shaft 30 is disposed such that the axial direction of the screw shaft 30 coincides with the up-down direction. Further, the screw shaft 30 is disposed on the right side of the motor 28. The screw shaft 30 is rotatably held by the casing 21.

The nut 31 is fixed to a nut holding member 32. The nut holding member 32 is fixed to the inside of the frame portion 25. That is, the nut 31 is fixed via the nut holding member 32 to the inside of the frame portion 25. A pulley 33 is fixed to an output shaft of the motor 28, and a pulley 34 is fixed to a lower end of the screw shaft 30. A belt 35 is wound around the pulleys 33 and 34. As illustrated in FIG. 5, the elevating mechanism 22 is accommodated in the casing 21 so as to overlap the elevating body 20 when viewed in the up-down direction. Specifically, the elevating mechanism 22 is accommodated in the casing 21 so as to overlap the frame portion 25 when viewed in the up-down direction.

Each of the guide mechanisms 23 includes a guide rail 38 and a guide block 39 engaged with the guide rail 38. The guide rail 38 is fixed to the inside of the casing 21 such that the longitudinal direction of the guide rail 38 coincides with the up-down direction. Further, the guide rails 38 are fixed on right and left ends of the inside of the casing 21. The guide blocks 39 are fixed to respective block holding members 40. The block holding members 40 are respectively fixed to the right and left side surfaces of the frame portion 25. That is, the guide blocks 39 are respectively fixed via the block holding members 40 to the right and left side surfaces of the frame portion 25, and the guide rails 38 and the guide blocks 39 are disposed on the opposite outer sides of the frame portion 25 in the right-left direction. Also, the guide rails 38 and the guide blocks 39 are accommodated in the casing 21.

In the present embodiment, when the motor 28 rotates, the elevating body 20 moves up and down relative to the casing 21 while being guided by the guide mechanisms 23. Note that one end of a cable bear (registered trademark) 42 is fixed to the inside of the frame portion 25, and the other end of the cable bear (registered trademark) 42 is fixed to the inside of the casing 21. The cable bear (registered trademark) 42 is disposed on the left side of the motor 28.

(Configuration of Arm and Hand Drive Mechanisms)

The robot 1 includes: an arm portion drive mechanism 45 (see FIG. 4) configured to extend and retract a part of the arm 6 including the first arm portion 16 and the second arm portion 17 by rotating the first arm portion 16 and the second arm portion 17; a third arm portion drive mechanism (not illustrated) configured to rotate the third arm portion 18; a hand drive mechanism (not illustrated) configured to rotate the hand 4; and a hand drive mechanism (not illustrated) configured to rotate the hand 5.

As illustrated in FIG. 4, the arm portion drive mechanism 45 includes a motor 46, a speed reducer 47 configured to decelerate the power of the motor 46 and transmit the decelerated power to the first arm portion 16, and a speed reducer 48 configured to decelerate the power of the motor 46 and transmit the decelerated power to the second arm portion 17. The motor 46 is fixed to a lower surface of the fixed portion 26a of the upper end frame portion 26. An output shaft of the motor 46 is disposed in the fixed portion 26a, and a body part of the motor 46 is disposed in the frame portion 25.

The speed reducer 47 constitutes a joint that connects the first arm portion 16 and the protruding portion 26b. The speed reducer 47 is a hollow speed reducer. A case body of the speed reducer 47 is fixed to the inside of the protruding portion 26b. An upper end surface of an output shaft of the speed reducer 47 is fixed to a lower surface on the base end of the first arm portion 16. The motor 46 and the speed reducer 47 are connected via a pulley 49 fixed to the output shaft of the motor 46, a pulley 50 fixed to an input shaft of the speed reducer 47, and a belt 51 wound around the pulley 49 and the pulley 50.

The speed reducer 48 constitutes a joint that connects the first arm portion 16 and the second arm portion 17. The speed reducer 48 is a hollow speed reducer in the same way as the speed reducer 47. The motor 46 and the speed reducer 48 are connected via the pulleys 49 and 50, the belt 51, and a pulley, a belt, and the like (not illustrated) disposed inside the first arm portion 16.

The third arm portion drive mechanism includes a motor and a speed reducer that is configured to decelerate the power of the motor and transmit the decelerated power to the third arm portion 18. The motor of the third arm portion drive mechanism is disposed inside the second arm portion 17, and the speed reducer of the third arm portion drive mechanism constitutes a joint that connects the second arm portion 17 and the third arm portion 18. The hand drive mechanism includes a motor and a speed reducer that is configured to decelerate the power of the motor and transmit the decelerated power to the hands 4 and 5. The motor and the speed reducer of the hand drive mechanism are disposed inside the third arm portion 18. Further, the speed reducer of the hand drive mechanism and the hands 4 and 5 are connected via a pulley and a belt (not illustrated).

(Configuration of Installation Member)

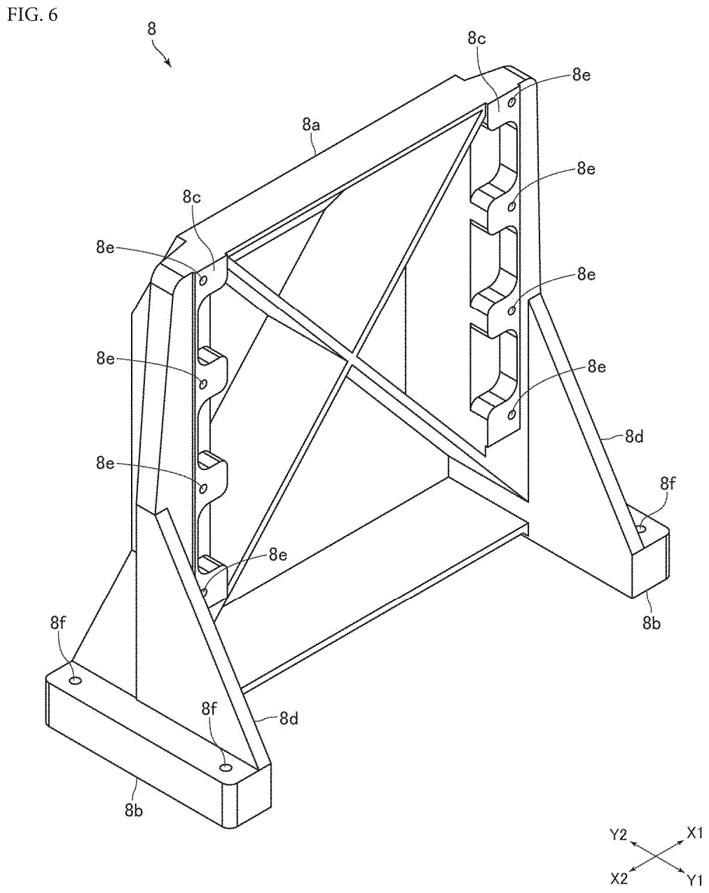

FIG. 6 is a perspective view of the installation member 8 illustrated in FIG. 1 A and FIG. 1B.

The installation member 8 is a cast component made of aluminum alloy. The installation member 8 includes a casing fixing portion 8a to which the casing 21 is fixed. That is, in the present embodiment, the casing 21 is fixed to the installation member 8. Further, the installation member 8 includes two fixed portions 8b fixed to the floor surface 14b (see FIG. 3) of the casing 14 of the EFEM 10. Note that the installation member 8 may be made of a metal other than an aluminum alloy, or may be a component obtained by cutting or may be another component. Moreover, in FIG. 3, the installation member 8 is simply illustrated.

The casing fixing portion 8a is disposed on the back side of the casing 14. The shape of the casing fixing portion 8a when viewed in the front-back direction has a substantially rectangular shape. An upper end of the casing fixing portion 8a is disposed below the upper end of the casing 21. The fixed portions 8b are connected to a lower end of the casing fixing portion 8a. Specifically, each of the two fixed portions 8b is connected to a lower end of each of right and left side surfaces of the casing fixing portion 8a. Further, the two fixed portions 8b are disposed such that the lower end portion of the casing 21 is interposed between the fixed portions 8b in the right-left direction. That is, one of the two fixed portions 8b is disposed on the right side of the casing 21, and the other of the two fixed portions 8b is disposed on the left side of the casing 21.

Contact surfaces 8c with which the back surface of the casing 21 contacts are formed on a front surface of the casing fixing portion 8a. Each of the contact surfaces 8c is a plane orthogonal to the front-back direction. Further, the contact surfaces 8c are formed on opposite sides in the right-left direction of the front surface of the casing fixing portion 8a. The contact surfaces 8c protrude slightly forward of other portions of the front surface of the casing fixing portion 8a. Front end portions of the respective fixed portions 8b protrude forward of the front surface of the casing fixing portion 8a. Reinforcement ribs 8d for connecting the front surface of the casing fixing portion 8a and the front end portions of the fixed portions 8b are formed at opposite ends of the casing fixing portion 8a in the right-left direction. Each of the ribs 8d is formed in a substantially triangular shape. Further, the two ribs 8d are disposed such that the lower end portion of the casing 21 is interposed between the ribs 8d in the right-left direction.

As illustrated in FIG. 5, the casing 21 is fixed to the casing fixing portion 8a by a plurality of screws 54 (see FIG. 1B) in a state where the back surface of the casing 21 is in contact with the contact surfaces 8c. In a state where the casing 21 is fixed to the installation member 8, the wiring box 24 is disposed on the upper side of the rib 8d disposed on the left side. A plurality of through holes 8e through which the screws 54 are to be inserted are formed in a portion of the casing fixing portion 8a in which the contact surfaces 8c are formed (see FIG. 6). The through holes 8e extend through the casing fixing portion 8a in the front-back direction.

Further, the installation member 8 is fixed to the floor surface 14b by a plurality of screws 55 in a state where lower surfaces of the respective fixed portions 8b are in contact with the floor surface 14b. That is, the robot 1 is installed on the floor surface 14b. A plurality of through holes 8f through which the screws 55 are to be inserted are formed in each of the fixed portions 8b (see FIG. 6). The through holes 8f extend through the fixed portions 8b in the up-down direction.

(Major Effects of the Present Embodiment)

As described above, in the present embodiment, the elevating mechanism 22 is accommodated in the casing 21 so as to overlap the frame portion 25 accommodated in the casing 21 when viewed in the up-down direction. Therefore, in the present embodiment, the width of the casing 21 in the front-back direction can be reduced as compared with a case where the elevating mechanism 22 is accommodated in the casing 21 while being displaced from the frame portion 25 in the front-back direction. That is, in the present embodiment, the width of the body part 7 in the front-back direction can be reduced as compared with a case where the elevating mechanism 22 is accommodated in the casing 21 while being displaced from the frame portion 25 in the front-back direction. As a result, the thickness of the body part 7 can be reduced.

Further, the robot 1 according to the present embodiment includes the installation member 8 for installing the body part 7 on the floor surface 14b. Accordingly, even if the thickness of the body part 7 is reduced, the body part 7 can be stably installed on the floor surface 14b. That is, in the present embodiment, even if the thickness of the body part 7 is reduced, the robot 1 can be stably installed on the floor surface 14b. Further, in the present embodiment, since the wiring box 24 is fixed to the upper end of the casing 21, the wiring box 24 can be prevented from interfering with the fixed portions 8b and the ribs 8d that are disposed on the outer sides of the casing 21 in the right-left direction.

(Modified Example of Robot)

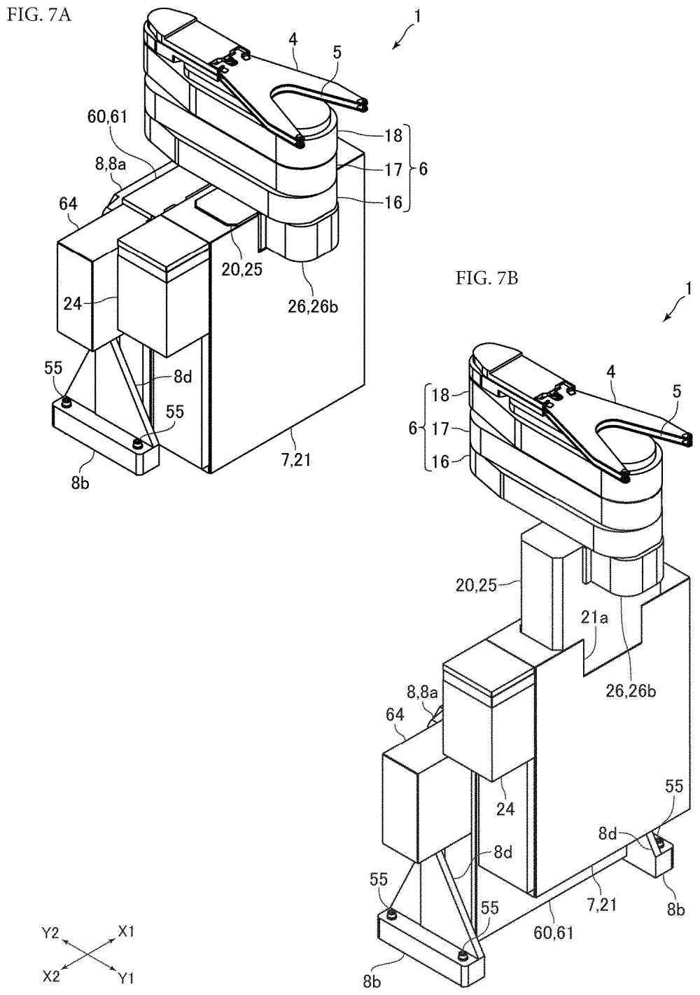

FIG. 7A is a perspective view of the robot 1 according to another embodiment of the present invention, and FIG. 7B is a perspective view of a state where the elevating body 20 and the casing 21 of the robot 1 illustrated in FIG. 7A are moved up.

In the embodiment described above, the robot 1 may include an elevating unit 60 configured to move up and down the body part 7. The elevating unit 60 includes an elevating body (not illustrated) to which the casing 21 is fixed, a casing 61 as a second casing configured to hold the elevating body such that the elevating body is movable up and down, an elevating mechanism (not illustrated) configured to move the elevating body up and down relative to the casing 61, guide mechanisms (not illustrated) configured to guide the elevating body in the up-down direction, and a wiring box 64 in which wires are accommodated. The elevating unit 60 is disposed on the front side of the casing fixing portion 8a, and the body part 7 is disposed on the front side of the elevating unit 60.

The casing 61 is formed in a box shape of a flat, substantially rectangular parallelepiped in the same way as the casing 21. The shape of the casing 61 when viewed in the up-down direction is a substantially rectangular shape having a long side in the right-left direction and a short side in the front-back direction, therefore being elongated in the right-left direction. The casing 61 has front and back surfaces that are planes orthogonal to the front-back direction, right and left side surfaces that are planes orthogonal to the right-left direction, and upper and bottom surfaces that are planes orthogonal to the up-down direction.

The width of the casing 61 in the right-left direction is equal to the width of the casing 21 in the right-left direction. Further, the height (length in the up-down direction) of the casing 61 is equal to the height (length in the up-down direction) of the casing 21. Further, the width of the casing 61 in the front-back direction is slightly smaller than the width of the casing 21 in the front-back direction. The wiring box 64 is formed in a box shape of a rectangular parallelepiped and is fixed to an upper end of the left side surface of the casing 61.

The elevating body of the elevating unit 60 includes a fixed portion to which the lower end portion of the back surface of the casing 21 is fixed. The fixed portion is disposed on the front side of the casing 61 and is disposed outside of the casing 61. Further, a portion of the elevating body other than the fixed portion is accommodated in the casing 61. The elevating mechanism of the elevating unit 60 is configured substantially in the same manner as the elevating mechanism 22 and is disposed in the casing 61 substantially in the same manner as the elevating mechanism 22 is disposed in the casing 21. Further, the guide mechanisms of the elevating unit 60 are configured in the same manner as the guide mechanisms 23 and are disposed in the casing 61 substantially in the same manner as the guide mechanisms 23 are disposed in the casing 21.

In this modified example, the casing 61 is fixed to the installation member 8. Specifically, the casing 61 is fixed to the casing fixing portion 8a by a plurality of screws in a state where the back surface of the casing 61 is in contact with the contact surfaces 8c. In a state where the casing 61 is fixed to the installation member 8, the upper end of the casing fixing portion 8a is disposed below an upper end of the casing 61. Further, in a state where the casing 61 is fixed to the installation member 8, the wiring box 64 is disposed above the rib 8d disposed on the left side. Moreover, the fixed portions 8b and the ribs 8d are disposed on the outer sides of the casings 21 and 61 in the right-left direction.

In this modified example, the casing 61 of the elevating unit 60 is fixed to the installation member 8 and the installation member 8 is installed on the floor surface 14b. Therefore, even if the thickness of the elevating unit 60 is reduced in addition to the body part 7, the body part 7 and the elevating unit 60 can be stably installed on the floor surface 14b. That is, even if the thickness of the elevating unit 60 is reduced in addition to the body part 7, the robot 1 can be stably installed on the floor surface 14b.

(Other Embodiments)

The embodiment described above is an example of at least an embodiment of the present invention, but the present invention is not limited thereto, and various modifications can be made without departing from the scope of the present invention.

In the embodiment described above, the entire frame portion 25 is accommodated in the casing 21 when the elevating body 20 is moved down to the lower limit position. Alternatively, when the elevating body 20 is moved down to the lower limit position, the upper end of the frame portion 25 may protrude upward of the upper surface of the casing 21. Further, in the embodiment described above, the elevating body 20 may not be provided with the protruding portion 26b. Furthermore, in the embodiment described above, although the two hands 4 and 5 are attached to the distal end of the third arm portions 18, one hand may be attached to the distal end of the third arm portion 18.

In the embodiment described above, the arm 6 includes three arm portions of the first arm portion 16, the second arm portion 17 and the third arm portion 18. Alternatively, the arm 6 may include two arm portions or four or more arm portions. Moreover, in the embodiment described above, the robot 1 is a robot used for transporting the wafers 2. Alternatively, the robot 1 may be a robot for transporting different objects to be transported such as glass substrates for liquid crystal.

While the description above refers to particular embodiments of the present invention, it will be understood that many modifications may be made without departing from the spirit thereof. The accompanying claims are intended to cover such modifications as would fall within the true scope and spirit of the present invention.

The presently disclosed embodiments are therefore to be considered in all respects as illustrative and not restrictive, the scope of the invention being indicated by the appended claims, rather than the foregoing description, and all changes which come within the meaning and range of equivalency of the claims are therefore intended to be embraced therein.

1. An industrial robot for use with an object to be transported, comprising:
a hand on which the object is mounted;
an arm having a distal end to which the hand is rotatably connected;
a body part to which a base end of the arm is rotatably connected; and
an installation member structured to install the body part on a floor surface, wherein
the body part comprises an elevating body having an upper surface to which the base end of the arm is rotatably connected, a casing configured to hold the elevating body such that the elevating body is movable up and down and to accommodate at least a part of a lower end of the elevating body, and an elevating mechanism configured to move the elevating body up and down, and
the elevating mechanism is accommodated in the casing so as to overlap the elevating body when viewed in an up-down direction.

2. The industrial robot according to claim 1, wherein
the casing is formed in a substantially rectangular shape that has a long side in a right-left direction and a short side in a front-back direction when viewed in the up-down direction, and
the elevating body comprises a frame portion formed in a substantially rectangular shape that has a long side in the right-left direction and a short side in the front-back direction when viewed in the up-down direction, the frame portion being accommodated in the casing when the elevating body is moved down.

3. The industrial robot according to claim 1, wherein
the casing is fixed to the installation member.

4. The industrial robot according to claim 3, wherein
the casing is formed in a substantially rectangular shape that has a long side in a right-left direction and a short side in a front-back direction when viewed in the up-down direction, and
the installation member comprises a casing fixing portion to which the casing is fixed, and two fixed portions to be fixed to the floor surface,
the casing fixing portion is disposed on one side of the casing in the front-back direction,
the fixed portions are connected to a lower end of the casing fixing portion, and
a first fixed portion of the two fixed portions is disposed on a first side of the casing in the right-left direction, and a second fixed portion of the two fixed portions is disposed on a second side of the casing in the right-left direction.

5. The industrial robot according to claim 4, wherein
the body part comprises a wiring box fixed to one side surface of the casing in the right-left direction, and
the wiring box is fixed to an upper end of the casing.

6. The industrial robot according to claim 1, comprising an elevating unit configured to move the body part up and down, wherein
a second casing that is a casing of the elevating unit is fixed to the installation member.
